(19) United States
(12) Patent Application Publication
(10) Pub. No.: US 2015/0000970 A1
(43) Pub. Date: Jan. 1, 2015

(54) WIRING BOARD

(71) Applicant: KYOCERA SLC Technologies Corporation, Yasu-shi (JP)

(72) Inventors: Masakazu IINO, Hikone-shi (JP); Teruya FUJISAKI, Moriyama-shi (JP); Takafumi OYOSHI, Osaka-shi (JP)

(73) Assignee: KYOCERA SLC Technologies Corporation, Yasu-shi (JP)

(21) Appl. No.: 14/317,538

(22) Filed: Jun. 27, 2014

(30) Foreign Application Priority Data
Jun. 28, 2013 (JP) 2013-135845
Oct. 31, 2013 (JP) 2013-226097

(51) Int. Cl. H05K 1/02; H05K 1/11

(52) U.S. Cl. CPC H05K 1/0271; H05K 1/113
USPC 174/262

(57) ABSTRACT

A wiring board includes an insulating layer having a lower layer conductor on a lower surface thereof, a plurality of semiconductor element connection pads arranged in a lattice pattern in a semiconductor element mounting portion 1a having a quadrangular shape on the insulating layer, a via hole formed in the insulating layer below each of the semiconductor element connection pads, and a via conductor filled in the via hole and formed integrally with each of the semiconductor element connection pads. The wiring board includes a reinforcing via hole formed in the insulating layer in an outer region outside an arrangement region of the semiconductor element connection pads in corner portions of the semiconductor element mounting portion, and a reinforcing via conductor formed in the reinforcing via hole.

### BACKGROUND OF THE INVENTION

(1) Field of the Invention

The present invention relates to a wiring board for mounting thereon a semiconductor element or the like.

(2) Description of the Related Art

As electronic appliances represented by mobile phones, music players, and the like have become highly functional in recent years, among wiring boards used therein, there are some wiring boards that are mounted with a highly functional and large-sized semiconductor element for arithmetic processing or the like. As disclosed in Japanese Unexamined Patent Publication No. 2006-073593, among such wiring boards, a wiring board of a stacked via structure is used.

FIG. 5A and FIG. 5B illustrate a conventional wiring board B on which such a large-sized semiconductor element is mounted. FIG. 5A is a top view of the wiring board B, and FIG. 5B is a cross sectional view taken along a line Y-Y in FIG. 5A.

The wiring board B includes an insulating board 21, a wiring conductor 22, and an insulating layer 23. A semiconductor element mounting portion 21a for mounting therein a large-sized semiconductor element S is formed in a center portion of an upper surface of the wiring board B.

The insulating board 21 is made of, for example, glass epoxy resin. A plurality of through holes 24 are formed to penetrate the insulating board 21 from an upper surface to a lower surface thereof. Part of the wiring conductor 22 is adhered to the upper and lower surfaces of the insulating board 21 and to a wall inside each of the through holes 24. The wiring conductor 22 on the upper surface of the insulating board 21 forms a lower layer conductor 25. In addition, the wiring conductor 22 on the lower surface of the insulating board 21 forms an external connection pad 26 to be connected to an external electric circuit board.

The insulating layer 23 is laminated on the upper surface of the insulating board 21. A plurality of via holes 27 are formed in the insulating layer 23. Part of wiring conductor 22 adheres to an upper surface of the insulating layer 23 and to a wall inside each of the via holes 27. The wiring conductor 22 adhering to the upper surface of the insulating layer 23 forms an upper layer conductor 28. In addition, the wiring conductor 22 adhering to the wall inside the via hole 27 forms a via conductor 29.

A plurality of semiconductor element connection pads 30 are arranged in a lattice pattern in the semiconductor element mounting portion 21a. The semiconductor element connection pad 30 is connected to a lower layer conductor 25 by means of the via conductor 29 formed immediately therebelow. Each of the semiconductor element connection pads 30 and the via conductor 29 located immediately therebelow are integrally formed.

Electrodes T of the semiconductor element S are connected to the semiconductor element connection pads 30 respectively corresponding thereto through solder, and the external connection pad 26 is connected to a wiring conductor of an external electric circuit board through solder. With this arrangement, the semiconductor element S operates by being electrically connected to the external electric circuit board.

However, as described above, when the semiconductor element S becomes larger as the electronic appliance has higher functionality, a large difference in thermal expansion and contraction between the semiconductor element S and the wiring board B is caused by thermal hysteresis when the semiconductor element S is connected to the wiring board B by solder, or the semiconductor element S operates. As a result, a large thermal stress is caused between the electrode T of the semiconductor element S and the semiconductor element connection pad 30 connected thereto. This thermal stress intensively works on the via conductor 29 which is formed integrally with each of the semiconductor element connection pads 30, and a connection portion with the lower layer conductor 25. Particularly, the largest thermal stress is generated in a corner portion of the semiconductor element mounting portion 21a remotely located from a center portion of the semiconductor element mounting portion 21a between the semiconductor element S and the wiring board B. For this reason, cracks tend to be caused in a joint surface between the via conductor 29 and the lower layer conductor 25 in the corner portions of the semiconductor element mounting portion 21a. As a result, there is a case where the semiconductor element S cannot be operated in a stable manner. Here, the center portion of the semiconductor element mounting portion 21a refers to a point of intersection of a pair of diagonal lines of the semiconductor element mounting portion 21a.

### SUMMARY OF THE INVENTION

An object of the present invention is to chiefly suppress occurrence of cracks between a via conductor and a lower layer conductor, which is caused by concentration of a thermal stress, and thereby provide a wiring board that can operate a semiconductor element in a stable manner.

Another object and advantage of the present invention will be made clear according to the following description.

A wiring board according to the present invention includes: an insulating board; an insulating layer including a lower layer conductor on a lower surface thereof and provided on a surface of the insulating board; a plurality of semiconductor element connection pads arranged in a lattice pattern in a semiconductor element mounting portion having a quadrangular shape on the insulating layer; a via hole formed in the insulating layer below each of the semiconductor element connection pads with the lower layer conductor as a bottom surface; and a via conductor filled in the via hole in a manner to be connected to the lower layer conductor, and formed integrally with each of the semiconductor element connection pads, in which the wiring board includes: a reinforcing via hole formed with the lower layer conductor as a bottom surface thereof in the insulating layer in an outer region outside an arrangement region of the semiconductor element connection pads at least in corner portions of the semiconductor element mounting portion; and a reinforcing via conductor formed in the reinforcing via hole in a manner to be connected to the lower layer conductor.

According to the wiring board of the present invention, the reinforcing via hole formed with the lower layer conductor as a bottom surface thereof in the insulating layer in an outer region outside an arrangement region of the semiconductor element connection pads in corner portions of the semiconductor element mounting portion, and the reinforcing via conductor formed in the reinforcing via hole in a manner to be connected to the lower layer conductor. Accordingly, a thermal stress caused by a difference in thermal expansion and contraction between the semiconductor element and the wiring board can be dispersed into a reinforcing via conductor. With this arrangement, it is possible to avoid an intensive action of the thermal stress exerted in a connection portion between the via conductor below the semiconductor element connection pad and the lower layer conductor in the corner portions of the semiconductor element mounting portion. As a result, it is possible to suppress occurrence of cracks in a connection portion between a via conductor and a lower layer conductor, and thereby provide a wiring board that can operate a semiconductor element in a stable manner.

### BRIEF DESCRIPTION OF THE DRAWINGS

FIG. 1A is a schematic top view illustrating one embodiment of a wiring board according to the present invention, and FIG. 1B is a cross sectional view taken along a line X-X in FIG. 1A.

FIG. 2 is a schematic cross sectional view illustrating another embodiment of a wiring board according to the present invention.

FIG. 3 is a schematic cross sectional view illustrating yet another embodiment of a wiring board according to the present invention.

FIG. 4 is a schematic cross sectional view illustrating yet another embodiment of a wiring board according to the present invention.

FIG. 5A is a schematic top view illustrating a conventional wiring board, and FIG. 5B is a cross sectional view taken along a line Y-Y in FIG. 5A.

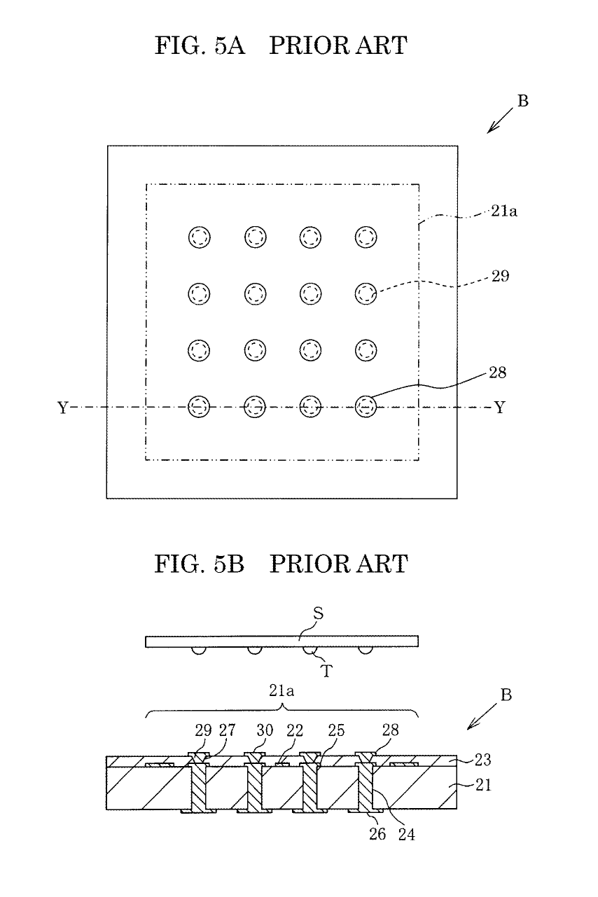

### DESCRIPTION OF THE PREFERRED EMBODIMENTS

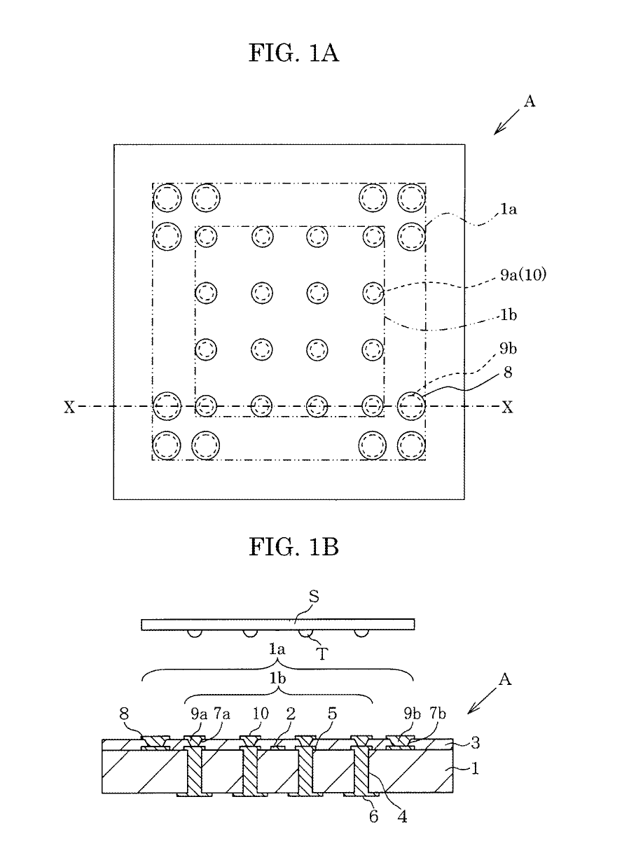

One example of an embodiment of a wiring board according to the present invention will be described with reference to FIG. 1A and FIG. 1B. FIG. 1A is a top view of a wiring board A, and FIG. 1B is a cross sectional view taken along a line X-X in FIG. 1A.

The wiring board A includes an insulating board 1, a wiring conductor 2, and an insulating layer 3. A semiconductor element mounting portion 1a having a quadrangular shape for mounting therein a semiconductor element S is formed in a center portion of an upper surface of the wiring board A. An example of the semiconductor element S includes a large-sized semiconductor element for arithmetic processing or the like.

The insulating board 1 is made of, for example, glass epoxy resin. A plurality of through holes 4 are formed to penetrate the insulating board 1 from an upper surface to a lower surface thereof. Part of the wiring conductor 2 adheres to the upper and lower surfaces of the insulating board 1. Part of the wiring conductor 2 is filled in the through hole 4 of the insulating board 1. The wiring conductor 2 on the upper surface of the insulating board 1 forms a lower layer conductor 5. The wiring conductor 2 on the lower surface of the insulating board 1 forms an external connection pad 6 to be connected to an external electric circuit board. The lower layer conductor 5 and the external connection pad 6 are electrically connected to each other by means of the wiring conductor 2 filled in the through hole 4.

For example, the insulating board 1 is formed in the following way. First, an electric insulating material is thermally cured under pressure to form an insulating plate. Examples of the electric insulating material include a material with glass cloth impregnated with a thermo-setting resin such as epoxy resin or bismaleimide triazine resin, or the like.

Next, the insulating board 1 is formed by forming the through holes 4 in an insulating plate by drilling, blasting, or laser processing.

The insulating layer 3 is laminated on the upper surface of the insulating board 1. A plurality of via holes 7a and a plurality of reinforcing via holes 7b are formed in the insulating layer 3. The insulating layer 3 is formed, for example, by laminating an electric insulating sheet on the insulating board 1 in a vacuum condition and thermally curing it thereafter. Examples of the electric insulating sheet include a sheet made of a thermo-setting resin such as epoxy resin or bismaleimide triazine resin, or the like. The via hole 7a and the reinforcing via hole 7b are formed by, for example, laser processing, with the lower layer conductor 5 as a bottom surface. After the laser processing, it is preferable to perform a desmear treatment on the via hole 7a and the reinforcing via hole 7b.

Part of the wiring conductor 2 adheres to the upper surface of the insulating layer 3. Part of the wiring conductor 2 is filled in the via hole 7a and the reinforcing via hole 7b of the insulating layer 3. The wiring conductor 2 adhering to the upper surface of the insulating layer 3 forms an upper layer conductor 8. The wiring conductor 2 filled in the via hole 7a forms a via hole conductor 9a that is formed integrally with the upper layer conductor 8. The wiring conductor 2 filled in the reinforcing via hole 7b forms a reinforcing via hole conductor 9b that is formed integrally with the upper layer conductor 8. The via hole conductor 9a and the reinforcing via hole conductor 9b connect the upper layer conductor 8 and the lower layer conductor 5 together. The upper layer conductor 8, the via hole conductor 9a, and the reinforcing via hole conductor 9b are made of a highly conductive material such as copper plating, and are formed by, for example, a well-known semi-additive method.

Part of the upper layer conductor 8 forms semiconductor element connection pads 10 that are individually connected to the electrodes T of the semiconductor element S in the semiconductor element mounting portion 1a. The plurality of semiconductor element connection pads 10 are arranged in a lattice pattern in the semiconductor element mounting portion 1a. The semiconductor element connection pad 10 is electrically connected to the lower layer conductor 5 by means of the via conductor 9a formed immediately therebelow. The lattice pattern may be a single pattern or a mixture of a plurality of patterns.

The electrodes T of the semiconductor element S are electrically connected to the semiconductor element connection pads 10 respectively corresponding thereto through the solder. Further, the external connection pads 6 are electrically connected to wiring conductors of the external electric circuit board through the solder, respectively. With this arrangement, the semiconductor element S is electrically connected to the external electric circuit board and operates.

As illustrated in FIG. 1A, in the wiring board A, the reinforcing via holes 7b and the reinforcing via conductors 9b are formed in the insulating layer 3 in a region outside an arrangement region 1b in which the semiconductor element connection pads 10 are arranged and in corner portions of the semiconductor element mounting portion 1a. Accordingly, by dispersing a thermal stress caused by a difference in thermal expansion and contraction between the semiconductor element S and the wiring board into the reinforcing via hole conductor 9b, it is possible to avoid intensive action of the thermal stress in a connection portion between the via conductor 9a and the lower layer conductor 5 below the semiconductor element connection pad 10 in the corner portions in the semiconductor element mounting portion 1a. With this arrangement, it is possible to suppress occurrence of cracks in the connection portion between the via conductor 9a and the lower layer conductor 5, and provide the wiring board A that can operate the semiconductor element S in a stable manner.

The via hole 7b is formed with the lower layer conductor 5 as a bottom surface. The reinforcing via conductor 9b is filled in the reinforcing via hole 7b so as to be electrically connected to the lower layer conductor 5.

A diameter of the via conductor 9a is about 15 to 60 μm, and a diameter of the reinforcing via conductor 9b is about 17 to 70 μm.

It is preferable that the diameter of the reinforcing via conductor 9b be larger than the diameter of the via conductor 9a by about 2 to 10 μm. It is preferable that a center-to-center distance between the via conductor 9a and the reinforcing via conductor 9b be 140 μm or smaller. When the center-to-center distance between the via conductor 9a and the reinforcing via conductor 9b is larger than 140 μm, it may be possible that the effect of dispersing the thermal stress caused by the difference in thermal expansion and contraction between the semiconductor element S and the wiring board A into the reinforcing via conductor 9b is reduced.

The present invention is not restricted to the embodiment described above, but can by variously modified and improved without departing from a spirit of the present invention.

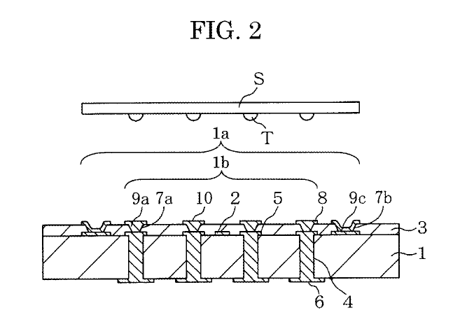

For example, as illustrated in FIG. 1B, in the embodiment described above, the reinforcing via conductor 9b is filled in the reinforcing via hole 7b. However, as illustrated in FIG. 2, a reinforcing via conductor 9c is not filled in the reinforcing via hole 7b, but may adhere to a side surface and a bottom surface of the reinforcing via hole 7b.

Further, as illustrated in FIG. 1A, in the embodiment described above, the reinforcing via holes 7b is not formed in the insulating layer 3 in a region outside an arrangement region 1b of the semiconductor element connection pads 10 other than the corner portions in the semiconductor element mounting portion la. However, the reinforcing via hole 7b and the reinforcing via conductor 9b may be formed in the insulating layer 3 in this region.

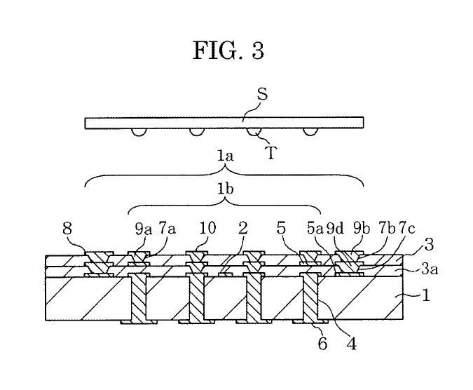

As illustrated in FIG. 1B, in the embodiment described above, the insulating layer 3 has a single layer structure. However, as illustrated in FIG. 3, two or more layers of insulating layers may be laminated. In such a case, a second insulating layer 3a on a lower side has a second lower layer conductor 5a in a lower surface, and a second reinforcing via hole 7c having the second lower layer conductor 5a as a bottom surface is formed immediately below the reinforcing via hole 7b. A second reinforcing via conductor 9d is filled in the second reinforcing via hole 7c.

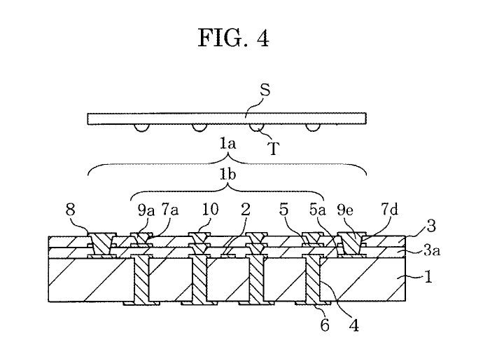

Further, as illustrated in FIG. 4, it is also possible to form an integrated reinforcing via hole 7d that penetrates from an upper surface of the insulating layer 3 to the second lower layer conductor 5a, and fill a reinforcing via conductor 9e therein.

When such a reinforcing via hole 7d is formed, it is preferable to perform filling so that, after the reinforcing via hole 7d is formed while an outer peripheral portion of the lower layer conductor 5 of the lower surface of the insulating layer 3 is left, a lower surface of the reinforcing via conductor 9e is connected to the second lower layer conductor 5a, and part of a side surface of the reinforcing via conductor 9e is connected to the outer peripheral portion of the lower layer conductor 5 described above.

In this way, by connecting the reinforcing via conductor 9e that is formed integrally to the lower layer conductor 5 in addition to the second lower layer conductor 5a, a connection area between the reinforcing via conductor 9e and each of the lower layer conductors 5 and 5a becomes larger, and the reinforcing via conductor 9e is firmly fixed in the reinforcing via hole 7d. As a result, even when a large thermal stress is caused by the difference in thermal expansion and contraction between the semiconductor element S and the wiring board, the thermal stress is dispersed into the reinforcing via conductor 9e that is firmly fixed. With this arrangement, it is possible to avoid an intensive action of the thermal stress exerted in the connection portion between the reinforcing via conductor 9a below the semiconductor element connection pad 10 and each of the lower layer conductors 5 and 5a in the corner portions of the semiconductor element mounting portion 1a.

What is claimed is:

1. A wiring board comprising:
an insulating board;
an insulating layer including a lower layer conductor on a lower surface thereof and provided on a surface of the insulating board;
a plurality of semiconductor element connection pads arranged in a lattice pattern in a semiconductor element mounting portion having a quadrangular shape on the insulating layer;
a via hole formed in the insulating layer below each of the semiconductor element connection pads with the lower layer conductor as a bottom surface; and
a via conductor filled in the via hole in a manner to be connected to the lower layer conductor, and formed integrally with each of the semiconductor element connection pads,
wherein the wiring board includes:
a reinforcing via hole formed in the insulating layer in an outer region outside an arrangement region of the semiconductor element connection pads at least in corner portions of the semiconductor element mounting portion with the lower layer conductor as a bottom surface; and
a reinforcing via conductor formed in the reinforcing via hole in a manner to be connected to the lower layer conductor.

2. The wiring board according to claim 1,
the outer region in which the reinforcing via hole is formed is inside the semiconductor element mounting portion.

3. The wiring board according to claim 1,
wherein the reinforcing via conductor has a diameter larger than a diameter of the via conductor.

4. The wiring board according to claim 1,
a center-to-center distance between the via conductor and the reinforcing via conductor located closes to the via conductor is 140 μm or smaller.

5. A wiring board comprising:
an insulating board;
a first insulating layer including a first lower layer conductor on a lower surface thereof and provided on a surface of the insulating board;
a plurality of semiconductor element connection pads arranged in a lattice pattern in a semiconductor element mounting portion having a quadrangular shape on the first insulating layer;
a via hole formed in the first insulating layer below each of the semiconductor element connection pads with the first lower layer conductor as a bottom surface;
a via conductor filled in the via hole in a manner to be connected to the first lower layer conductor, and formed integrally with each of the semiconductor element connection pads; and
a second insulating layer interposed between the insulating board and the first insulating layer and including a second lower layer conductor on a lower surface thereof,
wherein the wiring board includes:
a first reinforcing via hole formed in the first insulating layer in an outer region outside an arrangement region of the semiconductor element connection pads at least in corner portions of the semiconductor element mounting portion;
a first reinforcing via conductor filled in each of the first reinforcing via holes;
a second reinforcing via hole formed with the second lower layer conductor as a bottom surface in the second insulating layer immediately below the first reinforcing via hole; and
a second reinforcing via conductor filled in the second reinforcing via hole.

6. The wiring board according to claim 5,
wherein the first and second reinforcing via holes are formed as an integrated via hole that penetrates the first and second insulating layers, and
the first and second reinforcing via conductors are formed as an integrated via conductor in the integrated via hole.
